(19) United States
(12) Patent Application Publication
(10) Pub. No.: US 2006/0261366 A1
(43) Pub. Date: Nov. 23, 2006

(54) Integrated light-emitting device

(76) Inventor: Pi-Fu Yang, Keelung City (TW)

Correspondence Address: FROMMER LAWRENCE & HAUG, 745 FIFTH AVENUE- 10TH FL., NEW YORK, NY, 10151, US

(21) Appl. No.: 11/221,236

(22) Filed: Sep. 7, 2005

(30) Foreign Application Priority Data
May 19, 2005 (TW) 94116316

(51) Int. Cl. H01L 29/24

(52) U.S. Cl. 257/100

(57) ABSTRACT

An integrated light-emitting device includes a substrate, a reflecting layer containing at least one reflector cup molded over the substrate to define a cup-shaped recess and having a reflective surface in the cup-shaped recess, a light-generating source mounted on the substrate within the cup-shaped recess, an encapsulating layer molded over the cup-shaped recess and the light-generating source, and a brightness enhancement prism film attached onto the encapsulating layer and patterned to form a plurality of prism structures.

### CROSS-REFERENCE TO RELATED APPLICATION

This application claims priority of Taiwanese Application No. 094116316, filed on May 19, 2005.

### BACKGROUND OF THE INVENTION

1. Field of the Invention

The invention relates to a light-emitting device, more particularly to an integrated light-emitting device.

2. Description of the Related Art

Light emitting diodes (LEDs) are broadly utilized in various applications, such as displays, light-emitting devices, and the like, since they have advantages, such as low driving voltage and high light efficiency.

Referring to FIG. 1, a conventional light-emitting device including an LED die 12 as a light generating source is usually produced by drilling a printed circuit board 11 to form a recess 110 having a cup-shaped wall, plating a reflective metal substance on the cup-shaped wall of the recess 110 to form a reflective surface 10 on the cup-shaped wall of the recess 110, attaching the LED die 12 within the recess 110, and connecting electrically the LED die 12 to the printed circuit board 11 through a conductive wire 13. The reflective surface 10 directs the light emitted from the LED die 12 in an outward direction. Additionally, a light-transmissive encapsulating layer 14 can be formed to encapsulate the LED die 12 so as to protect the LED die 12 from damage and to provide a lens-like configuration such that the light emitted from the LED die 12 can be projected at a desired angle.

However, the aforesaid prior art has the following disadvantages:

(1) The aforesaid method for making the conventional light-emitting device involves lengthy and complex manufacturing steps, such as drilling, milling and polishing. With the complex processing steps, it is difficult to control the depth, dimension, angle and position of the recess 110 precisely, which in turn leads to higher yield loss of end products. Additionally, the drilling, milling and polishing steps are tedious and expensive. Furthermore, any error caused by the drilling step will affect the overall performance of the light-emitting device.

(2) The tools for drilling, milling and polishing are easily worn out. In order to produce a smooth cup-shaped wall, it is required to replace the tools periodically. Therefore, the production cost is relatively high.

(3) The recess 110 formed by the conventional method usually takes the form of a round shape, which in turn limits the reflective angle of the reflective surface 10.

(4) Since the reflective surface 10 is deposited on the cup-shaped wall of the recess 110 by plating, the adhesive strength between the reflective surface 10 and the cup-shaped wall of the recess 110 is insufficient, which may in turn cause delamination of the reflective surface 10 from the cup-shaped wall of the recess 110 due to high temperatures produced during operation of the light-emitting device.

U.S. Pat. No. 5,043,716 discloses an electronic display, which is produced by filling a lens matrix with potting compound, placing a reflector matrix in the lens matrix so as to fill light pipe cavities with the potting compound, and placing a circuit board having a plurality of LED dies over the reflector matrix. However, the method for producing the electronic display is lengthy and complex. In addition, the bonding strength between the reflector matrix and the circuit board is inferior. Furthermore, sufficient thickness and hardness are required for making the lens matrix having separate convex lens elements.

### SUMMARY OF THE INVENTION

Therefore, the object of the present invention is to provide an integrated light-emitting device, which has superior optical efficiency, and which can be produced in a simple, fast and cost-efficient manner.

In one aspect of this invention, an integrated light-emitting device includes a substrate, a reflecting layer containing at least one reflector cup molded over the substrate to define a cup-shaped recess and having a reflective surface in the cup-shaped recess, a light-generating source mounted on the substrate within the cup-shaped recess, an encapsulating layer molded over the cup-shaped recess and the light-generating source, and a brightness enhancement prism film attached onto the encapsulating layer and patterned to form a plurality of prism structures.

In another aspect of this invention, a method for making an integrated light-emitting device includes the steps of: (a) transfer-molding a reflecting layer having at least one reflector cup over a substrate to define a cup-shaped recess in the reflector cup; (b) mounting a light-generating source on the substrate within the cup-shaped recess; (c) transfer-molding an encapsulating layer over the cup-shaped recess and the light-generating source; and (d) attaching a brightness enhancement prism film onto the encapsulating layer.

### BRIEF DESCRIPTION OF THE DRAWINGS

Other features and advantages of the present invention will become apparent in the following detailed description of the preferred embodiment with reference to the accompanying drawings, of which:

FIG. 1 is a sectional view of a conventional light-emitting device;

FIG. 2 is a sectional view of the preferred embodiment of an integrated light-emitting device according to this invention;

FIG. 3 is a flow diagram of the method for making the integrated light-emitting device according to this invention; and

FIGS. 4 to 16 are schematic sectional views showing consecutive steps of the method of FIG. 3.

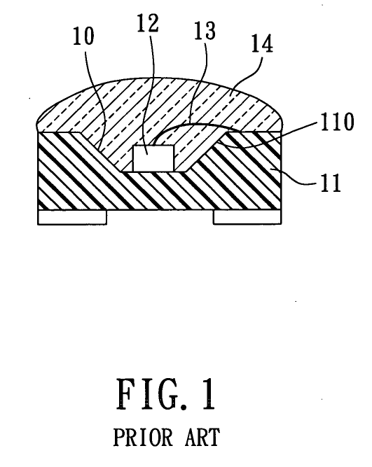

### DETAILED DESCRIPTION OF THE PREFERRED EMBODIMENT

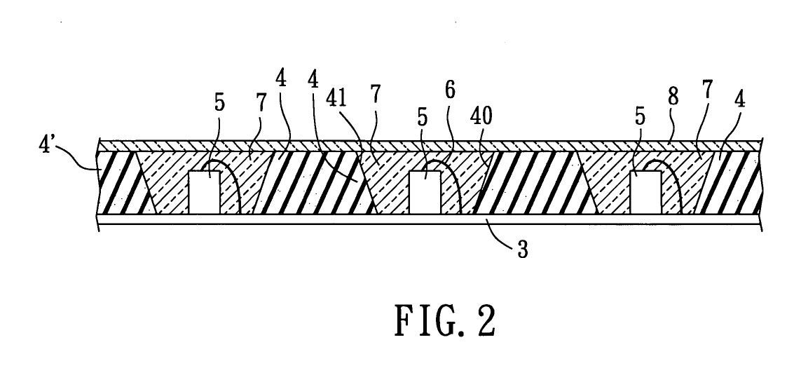

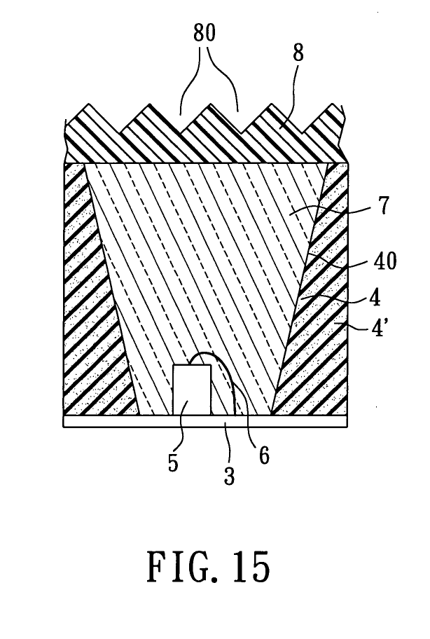

Referring to FIG. 2, the preferred embodiment of an integrated light-emitting device according to this invention is shown to include a substrate 3, a reflecting layer 4′, a plurality of light-generating sources 5, a plurality of conductive wires 6, an encapsulating layer 7, and a brightness enhancement prism film 8. The reflecting layer 4′ is molded over the substrate 3, and contains a plurality of reflector cups 4 each of which defines a cup-shaped recess 40. Each of the reflector cups 4 has a reflective surface 41 in the cup-shaped recess 40. Each of the light-generating sources 5 is mounted on the substrate 3 within the cup-shaped recess 40 of a corresponding one of the reflector cups 4. Each of the conductive wires 6 connects electrically a corresponding one of the light-generating sources 5 to the substrate 3. The encapsulating layer 7 is molded over the cup-shaped recess 40 of each of the reflector cups 4 and the light-generating sources 5. The brightness enhancement prism film 8 is attached onto the encapsulating layer 7 and is patterned to form a plurality of prism structures 80 (best shown in FIG. 15).

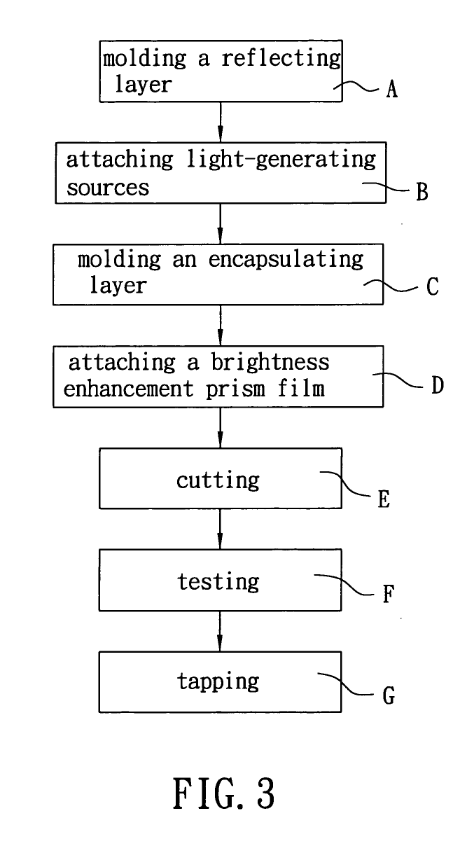

Referring to FIG. 3, the method for making the integrated light-emitting device according to this invention includes the steps of:

A) Molding the Reflecting Layer 4′:

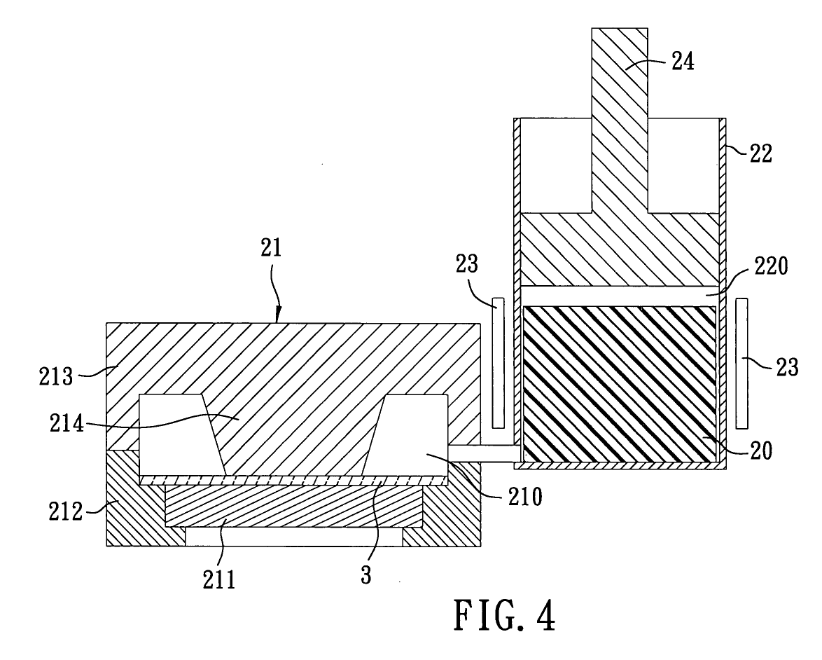

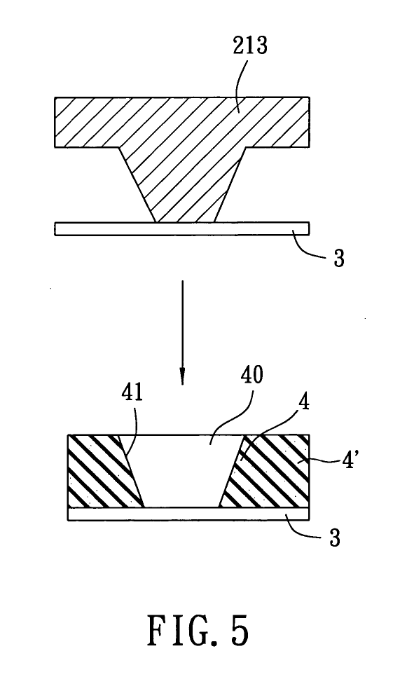

Referring to FIGS. 4 and 5, the reflecting layer 4′ is molded over the substrate 3 by transfer-molding. The transfer-molding can be used to produce a thin and flat thermoplastic component having a plurality of recesses. The thermoplastic component produced by transfer-molding has superior forming quality and homogeneity.

The substrate 3 is disposed on a base 211 of a transfer-molding tool 21. The base 211 together with the substrate 3 is then mounted on a lower mold portion 212, and an upper mold portion 213 is placed on the lower mold portion 212 and the substrate 3. The upper mold portion 213 has a cup-shaped portion 214 and cooperates with the lower mold portion 212 to define a mold cavity 210 corresponding to the shape of each of the reflector cups 4 and containing the substrate 3 therein. The cup-shaped portion 214 of the upper mold portion 213 of the transfer-molding tool 21 has a forming surface conforming to a contour of the cup-shaped recess 40. The forming surface of the cup-shaped portion 241 has a smooth outer surface. The cup-shaped portion 214 of the transfer-molding tool 21 diverges in a direction away from the substrate 3.

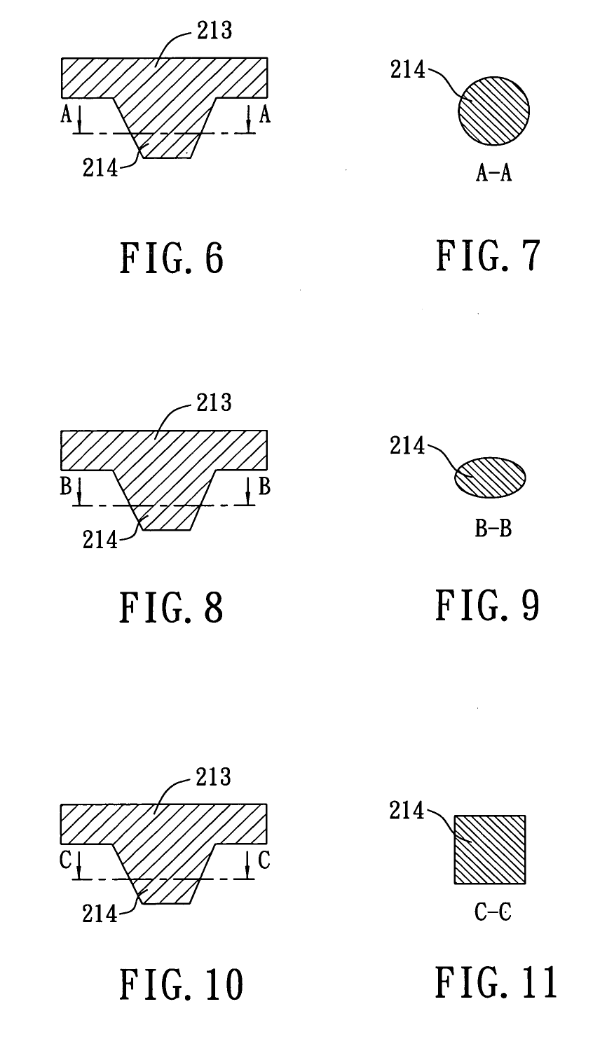

Referring to FIGS. 6 to 11, the cup-shaped portion 241 of the transfer-molding tool 21 may be provided with various shapes. For example, the cup-shaped portion 241 of the transfer-molding tool 21 can have a circular cross-section (as shown in FIG. 8), an elliptical cross-section (as shown in FIG. 10), or a rectangular cross-section (as shown in FIG. 11).

The material 20 for forming the reflecting layer 4′ is contained in a heating chamber 220 of an extruder 22, and is molten by heating means 23. The molten material 20 is forced into the mold cavity 210 by a plunger 24 so as to fill the mold cavity 210 completely. The molten material 20 is cured and solidified in the mold cavity 210 to form the reflecting layer 4′. After separating the upper mold portion 213 from the lower mold portion 212, the reflecting layer 4′ integral with the substrate 3 can be obtained.

During transfer-molding, the material 20 can be molten completely prior to entering into the mold cavity 210, and can be forced into the mold cavity 210 quickly so as to increase the fluidity of the material 20 within the mold cavity 210. Therefore, each of the reflector cups 4 can be shaped homogeneously, and is formed with the reflective surface 41 which is smooth and which has a good reflective effect. Specifically, when the material 20 contains a light-reflective additive, the light-reflective additive can be distributed in the reflector cups 4 and over the reflective surface 41 of each of the reflector cups 4 so as to further enhance the reflective effect.

The substrate 3 is made of a material which is resistant to high temperatures and to chemical corrosion. In the preferred embodiment, the substrate 3 is a printed circuit board, which can be thin sheet or flexible. In other embodiments, the substrate 3 can be a ceramic board, a lead frame, or the like.

Furthermore, the reflecting layer 4, is configured in a shape of a flat plate or a thin film. The cup-shaped recess 40 of each of the reflector cups 4 can have many different shapes, such as circular, elliptical, or rectangular cross-sectional shape, which vary according to the shape of cup-shaped portion 214 of the of the transfer-molding tool 21. The materials suitable for making the reflecting layer 4′ is light reflective, and include epoxy resin, silicone, plastic, metal, and the like, or any combination thereof. The light-reflective additive, which can be embedded into the material for the reflecting layer 4′, can be a metallic substance, pigment, nano-particle, and the like, or any combination thereof.

B) Attaching the Light-Generating Sources 5:

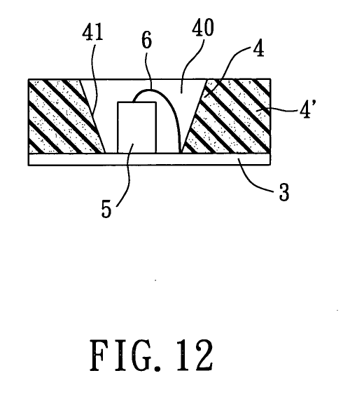

Referring to FIG. 12, each of the light-generating sources 5 is attached onto the substrate 3 within the cup-shaped recess 40 of each of the reflector cups 4, and is connected electrically to the substrate 3 through one of the conductive wires 6. The light-generating sources 5 can be driven by the substrate 3 so as to emit light. Examples of the light-generating sources 5 useful in this invention include a light-emitting diode of GaN, InGaN, AlInGaP, or GaP, or any device capable of performing the function of emitting light in response to an electrical signal. Preferably, the wavelength of the light emitted by the light-generating sources 5 ranges from ultraviolet to infrared spectrum. Additionally, the light-generating sources 5 can be other types of electronic elements, and the number thereof can be more than one for the cup-shaped recess 40 of each of the reflector cups 4.

C) Molding the Encapsulating Layer 7:

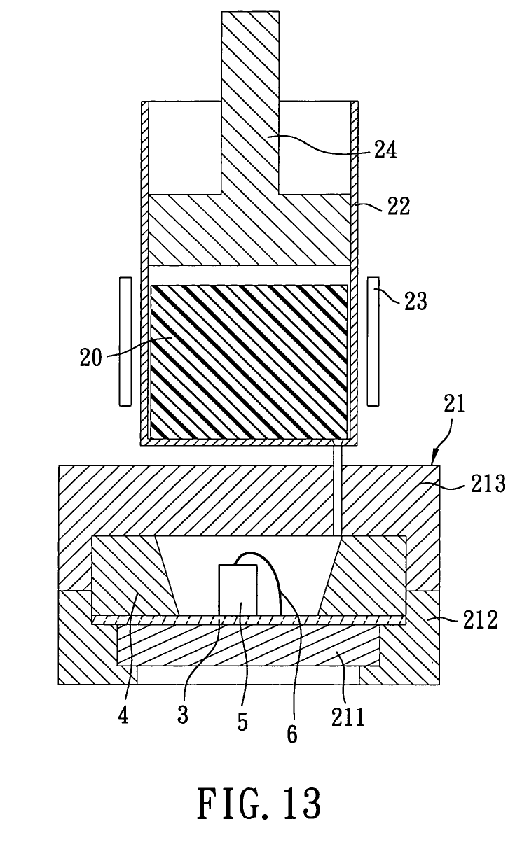

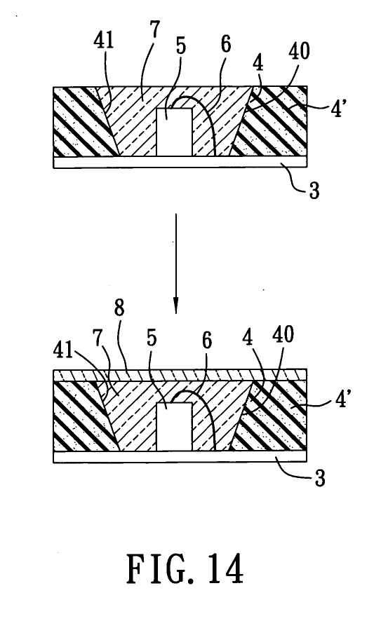

Referring to FIGS. 13 and 14, the encapsulating layer 7 is molded over the cup-shaped recess 40 of each of the reflector cups 4 and the light-generating sources 5 by transfer-molding. The transfer-molding process and the tool thereof are similar to those described above in connection with the molding of the reflecting layer 4′. The encapsulating layer 7 is adhered to the reflective surface 41 of each of the reflector cups 4, and is flush with the reflector cups 4. The encapsulating layer 7 is formed by transfer-molding using a light-transmissive material, such as epoxy resin, silicone, plastic, and the like. A light-converting material can be added into the light-transmissive material so as to enhance the emission and excitation of light. The light-converting material can be a light-diffusing substance, a colored dye, a pigment, a UV inhibitor, and the like, or any combination thereof.

D) Attaching a Brightness Enhancement Prism Film 8:

Referring to FIG. 14, the prism film 8 is then attached onto the encapsulating layer 7 and the reflecting layer 4′ using transparent adhesive, optical gel, and the like.

Referring to FIG. 15, the prism film 8 is a light-transmissive film, is patterned to form a plurality of prism structures 80, and can be obtained from 3M's Vikuiti™ Brightness Enhancement Film (BEF) III-10T, which is a translucent microstructured surface. The prism film 8 utilizes refraction and reflection to increase the efficiency of light. The prism film 8 refracts light within the viewing cone toward the viewer. Light outside this angle is reflected back and recycled until it exits at the proper angle.

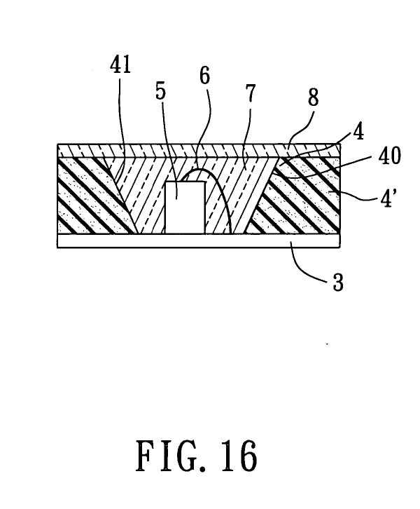

If required, the integrated light-emitting device thus produced can be further processed by cutting to obtain a plurality of light-emitting elements, as shown in FIG. 16, prior testing and tapping.

The reflecting layer 4′ exhibits functional bonding characteristics to the substrate 3 and the encapsulating layer 7, and thereby contributes to the structural integrity of the integrated light-emitting device. The bonding strength between the prism film 8 and the reflecting layer 4′ and the encapsulating layer 7 can also be improved. The reflecting layer 4′ having a thin and uniform configuration can be formed via transfer-molding. Furthermore, since the prism film 8 utilizes refraction and reflection to increase the efficiency of light, it is not necessary to use an additional lens in this invention. Additionally, the prism film 8 is flexible and has a relatively small thickness. Therefore, the total thickness of the integrated light-emitting device can be reduced, and the integrated light-emitting device having a flexible structure can be produced.

In view of the aforesaid, the integrated light-emitting device of this invention has superior optical efficiency, and can be produced in a simple, fast and cost-efficient manner as compared to the prior art.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. An integrated light-emitting device, comprising:
a substrate;
a reflecting layer containing at least one reflector cup molded over said substrate to define a cup-shaped recess and having a reflective surface in said cup-shaped recess;
a light-generating source mounted on said substrate within said cup-shaped recess;
an encapsulating layer molded over said cup-shaped recess and said light-generating source; and
a brightness enhancement prism film attached onto said encapsulating layer and patterned to form a plurality of prism structures.

2. The integrated light-emitting device as claimed in claim 1, wherein said substrate is a printed circuit board.

3. The integrated light-emitting device as claimed in claim 2, wherein said substrate is a flexible printed circuit board.

4. The integrated light-emitting device as claimed in claim 1, wherein said substrate is a ceramic board.

5. The integrated light-emitting device as claimed in claim 1, wherein said substrate is a lead frame.

6. The integrated light-emitting device as claimed in claim 1, wherein said light-generating source is a light-emitting diode.

7. The integrated light-emitting device as claimed in claim 1, wherein each of said reflecting layer and said encapsulating layer is formed by molding an epoxy resin.

8. The integrated light-emitting device as claimed in claim 1, wherein each of said reflecting layer and said encapsulating layer is formed by molding silicone.

9. The integrated light-emitting device as claimed in claim 1, wherein said reflector cup includes a light-reflective material.

10. The integrated light-emitting device as claimed in claim 9, wherein said reflecting layer includes an epoxy resin which contains a light-reflective additive embedded therein, said additive being selected from the group consisting of a metallic substance, pigments, and nano-particles.

11. The integrated light-emitting device as claimed in claim 9, wherein said reflecting layer includes silicone which contains a light-reflective additive embedded therein, said additive being selected from the group consisting of a metallic substance, pigments, and nano-particles.

12. The integrated light-emitting device as claimed in claim 1, wherein said cup-shaped recess of said reflector cup has many different shapes.

13. The integrated light-emitting device as claimed in claim 1, wherein said reflecting layer is configured in a shape selected from the group consisting of a flat plate and a thin film.

14. The integrated light-emitting device as claimed in claim 1, wherein said encapsulating layer is formed by molding a light-transmissive epoxy resin.

15. The integrated light-emitting device as claimed in claim 1, wherein said encapsulating layer includes an epoxy resin containing a light converting material.

16. The integrated light-emitting device as claimed in claim 15, wherein said light converting material is selected from the group consisting of a light-diffusing substance, a colored dye, and a UV inhibitor.

17. A method for making an integrated light-emitting device, comprising the steps of:
(a) transfer-molding a reflecting layer having at least one reflector cup over a substrate to define a cup-shaped recess in the reflector cup;
(b) mounting a light-generating source on the substrate within the cup-shaped recess;
(c) transfer-molding an encapsulating layer over the cup-shaped recess and the light-generating source; and
(d) attaching a brightness enhancement prism film onto the encapsulating layer.

18. The method as claimed in claim 17, wherein the step (a) is conducted by placing a transfer-molding tool on the substrate, the transfer-molding tool including a cup-shaped portion having a forming surface conforming to a contour of the cup-shaped recess.

19. The method as claimed in claim 18, wherein the cup-shaped portion may be provided with various shapes.

20. The method as claimed in claim 18, wherein the forming surface of the cup-shaped portion has a smooth outer surface.

21. The method as claimed in claim 1.8, wherein the cup-shaped portion of the transfer-molding tool diverges in a direction away from the substrate, and has an elliptical cross-section.

22. The method as claimed in claim 18, wherein the cup-shaped portion of the transfer-molding tool diverges in a direction away from the substrate, and has a circular cross-section.

23. The method as claimed in claim 18, wherein the cup-shaped portion of the transfer-molding tool diverges in a direction away from the substrate, and has a rectangular cross-section.

24. The method as claimed in claim 17, wherein the reflecting layer is formed from an epoxy resin including a light-reflective material.

25. The method as claimed in claim 17, wherein the epoxy resin includes a light-reflective additive embedded therein, the light-reflective additive being selected from the group consisting of a metallic substance, pigments, and nano-particles.

26. The method as claimed in claim 17, wherein a light-transmissive epoxy rein is used to form the encapsulating layer.

27. The method as claimed in claim 17, wherein the encapsulating layer includes a light converting material.

28. The method as claimed in claim 27, wherein the light converting material is selected from the group consisting of a light-diffusing substance, a colored dye, and a UV inhibitor.
